(19) United States
(12) Patent Application Publication
(10) Pub. No.: US 2021/0210107 A1
(43) Pub. Date: Jul. 8, 2021

(54) INFORMATION PROCESSING APPARATUS, INFORMATION PROCESSING SYSTEM, PROGRAM, AND INFORMATION PROCESSING METHOD

(71) Applicant: Sony Semiconductor Solutions Corporation, Kanagawa (JP)

(72) Inventors: Tomonobu Hayakawa, Kanagawa (JP); Takaaki Ishiwata, Kanagawa (JP)

(21) Appl. No.: 17/058,763

(22) PCT Filed: Jun. 12, 2019
(86) PCT No.: PCT/JP2019/023220

§ 371 Date: Nov. 25, 2020

(30) Foreign Application Priority Data
Jun. 25, 2018 (JP) 2018-119738

(51) Int. Cl. G10L 19/022; H03M 7/30

(52) U.S. Cl. CPC G10L 19/022; H03M 7/6005; H03M 7/3053

(57) ABSTRACT

[Object] To provide an information processing apparatus, an information processing system, a program, and an information processing method that are capable of executing decoding without necessity of a large memory resource.

[Solving Means] An information processing apparatus according to the present technology includes a decoder. The decoder acquires a top position of each piece of data of a plurality of channels included in each frame of compressed audio data and decodes the data of the plurality of channels for each block with a predetermined size from the top position.

### TECHNICAL FIELD

The present technology relates to an information processing apparatus, an information processing system, a program, and an information processing method that are related to decoding of compressed audio data.

### BACKGROUND ART

Some compression codecs for sound, such as a free lossless audio codec (FLAC), have a large frame length. When data compressed by such a compression codec having a large frame length is decoded, both a memory for storing compressed data (elementary stream) and a memory for storing pulse code modulation (PCM) data need to have a large size (see, for example, Patent Literature 1).

### CITATION LIST

### Patent Literature

Patent Literature 1: JP-A-2009-500681

### DISCLOSURE OF INVENTION

### Technical Problem

However, when a compression codec having a large frame length is used, it may be difficult to allocate a large memory resource from the viewpoint of power, size, and cost requested for a device.

In particular, since the condition of the device is limited in a wearable terminal, IoT (Internet of Things), M2M (Machine to Machine) via a mesh network, or the like, it is not easy to allocate a memory resource. On the other hand, applications of those devices also have a request to use high-resolution and lossless compression codecs such as the FLAC.

In view of the circumstances as described above, it is an object of the present technology to provide an information processing apparatus, an information processing system, a program, and an information processing method that are capable of executing decoding without necessity of a large memory resource.

### Solution to Problem

In order to achieve the above object, an information processing apparatus according to the present technology includes a decoder.

The decoder acquires a top position of each piece of data of a plurality of channels included in each frame of compressed audio data and decodes the data of the plurality of channels for each block with a predetermined size from the top position.

According to this configuration, since the decoder decodes the compressed audio data for each block, it is possible to reduce the memory resource necessary for decoding. In particular, compression codecs such as the FLAC have a large frame size, which usually makes it difficult for a device with a small memory resource to execute decoding. On the other hand, if decoding is executed in units of blocks, even a device with a small memory resource can execute decoding.

Each frame of the compressed audio data may include data of a first channel and data of a second channel sequentially from a top of the frame.

The decoder may decode a first block from the top position in the first channel, decode a second block from the top position in the second channel, decode a third block from an end position of the first block in the first channel, and decode a fourth block from an end position of the second block in the second channel.

The information processing apparatus may further include a parser unit that specifies the top position.

The parser unit may decode the compressed audio data and specify the top position.

Each frame of the compressed audio data may include data of a first channel and data of a second channel sequentially from a top of the frame.

The parser unit may decode the data of the first channel and specify an end position of the data of the first channel as a top position of the data of the second channel.

The parser unit may specify the top position from meta-information of the compressed audio data.

The parser unit may specify the top position and generate meta-information of the compressed audio data including the top position.

The decoder may decode the data of the plurality of channels for each block with the predetermined size from the top position by using the top position included in the meta-information.

The parser unit may generate compressed audio data including the meta-information.

The parser unit may generate a meta-information file including the meta-information.

The information processing apparatus may further include a rendering unit that renders audio data of the first block and audio data of the second block after the decoder decodes the first block and the second block.

In order to achieve the above object, an information processing system according to the present technology includes a first information processing apparatus and a second information processing apparatus.

The first information processing apparatus includes a decoder that acquires a top position of each piece of data of a plurality of channels included in each frame of compressed audio data and decodes the data of the plurality of channels for each block with a predetermined size from the top position.

The second information processing apparatus includes a parser unit that specifies the top position.

In order to achieve the above object, a program according to the present technology causes an information processing apparatus to operate as a decoder.

The decoder acquires a top position of each piece of data of a plurality of channels included in each frame of compressed audio data and decodes the data of the plurality of channels for each block with a predetermined size from the top position.

In order to achieve the above object, an information processing method according to the present technology includes, by a decoder, acquiring a top position of each piece of data of a plurality of channels included in each frame of compressed audio data and decoding the data of the plurality of channels for each block with a predetermined size from the top position.

### Advantageous Effects of Invention

As described above, according to the present technology, it is possible to provide an information processing apparatus, an information processing system, a program, and an information processing method that are capable of executing decoding without necessity of a large memory resource. Note that the effects described here are not necessarily limitative, and any of the effects described in the present disclosure may be provided.

### BRIEF DESCRIPTION OF DRAWINGS

FIG. 1 is a schematic diagram showing a usage mode of a memory resource in a general decoding process.

FIG. 2 is a schematic diagram showing a decoding method for compressed audio data in the decoding process.

FIG. 3 is a schematic diagram showing a data structure of audio data generated by the decoding process.

FIG. 4 is a block diagram showing a functional configuration of an information processing apparatus according to a first embodiment of the present technology.

FIG. 5 is a schematic diagram showing a channel top position in the compressed audio data.

FIG. 6 is a schematic diagram showing a mode of decoding (specifying channel top position) by a parser unit of the information processing apparatus.

FIG. 7 is a schematic diagram showing a mode of decoding by a decoder of the information processing apparatus.

FIG. 8 is a schematic diagram showing a data structure of audio data generated by the decoder of the information processing apparatus.

FIG. 9 is a schematic diagram showing the order of decoding by the decoder of the information processing apparatus.

FIG. 10 is a schematic diagram showing a data structure of audio data generated by the decoder of the information processing apparatus.

FIG. 11 is a block diagram showing a hardware configuration of the information processing apparatus.

FIG. 12 is a block diagram showing a functional configuration of an information processing apparatus according to a second embodiment of the present technology.

FIG. 13 is an example of a meta-information file generated by a parser unit of the information processing apparatus.

FIG. 14 is an example of a meta-information embedded portion of compressed audio data with meta-information generated by the parser unit of the information processing apparatus.

### MODE(S) FOR CARRYING OUT THE INVENTION

(Regarding Memory Resource in General Decoding)

Prior to describing embodiments of the present technology, a description will be given on a usage mode of a memory resource in a general decoding process for compressed audio data.

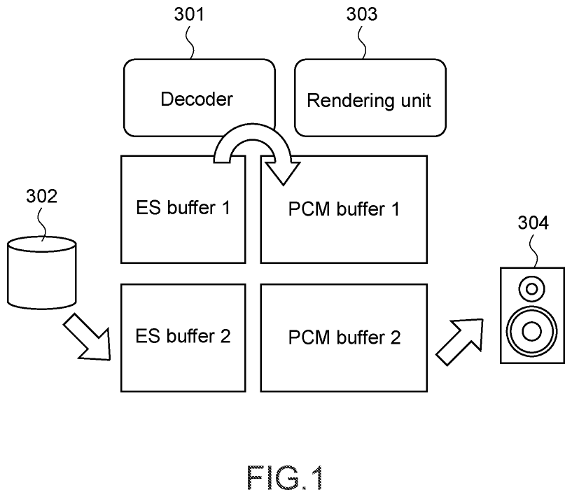

FIG. 1 is a schematic diagram showing a usage mode of a memory resource in a general decoding process. Here, a process of decoding compressed audio data (elementary stream (ES)) compressed by a free lossless audio codec (FLAC) and generating pulse code modulation (PCM) data will be described.

A decoder 301 reads an ES from storage 302 and stores it in an ES buffer 1. In addition, the decoder 301 decodes the compressed audio data of the ES buffer 1 and stores PCM data generated by decoding in a PCM buffer 1.

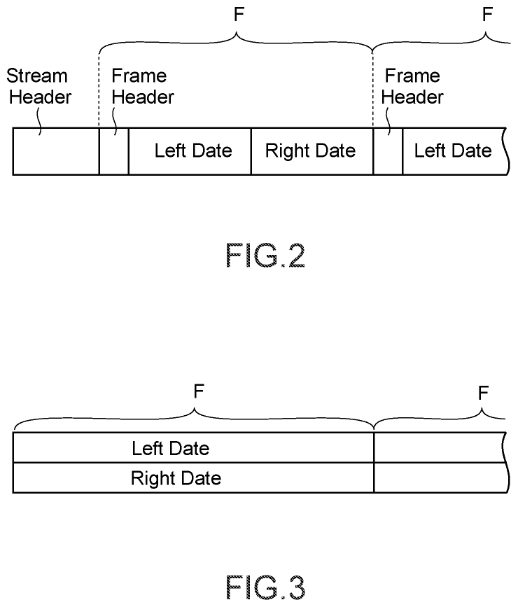

FIG. 2 is a schematic diagram showing a data structure of ES data of stereo audio. As shown in the figure, the ES includes a stream header (Stream Header), frame headers (Frame Header), left-channel data (Left Date), and right-channel data (Right Date). The ES includes a plurality of frames F. Each frame F includes a frame header, left-channel data, and right-channel data.

The decoder 301 stores the ES of one frame in the ES buffer 1 and decodes the ES. Further, during decoding, the decoder 301 needs to read the ES of the next frame beforehand from the storage 302 and stores the read ES in an ES buffer 2.

FIG. 3 is a schematic diagram showing a data structure of the PCM data. As shown in the figure, one frame F includes left-channel data (Left Date) and right-channel data (Right Date). A rendering unit 303 renders the PCM data to generate an audio signal, and causes a speaker 304 to output the audio signal.

While the rendering unit 303 renders the PCM data of the PCM buffer 2, the decoder 301 decodes the

ES of the next frame into the PCM data and stores the decoded ES in the PCM buffer 1.

In such a manner, the general decoding process simultaneously needs at least four memory buffers of the ES buffer 1, the ES buffer 2, the PCM buffer 1, and the PCM buffer 2.

Here, in some audio codecs such as the FLAC, the size of one frame is large, and the amount of necessary memory buffers is also large. For example, if the size of one frame is approximately 500 KB, four memory buffers need approximately 2 MB. Such memory buffers are difficult to allocate in a device with a limited memory resource, such as IoT (Internet of Things) or M2M (Machine to Machine).

(Regarding Divided Decoding)

In a case where decoding is executed in units of blocks as described above, a large memory resource is necessary. Here, if decoding can be executed in units of frames or smaller (divided decoding), the memory resource used for decoding can be reduced.

In normal audio compression, sampling is performed on a sampling frequency of a frame time. In such a manner, the data is converted into a collection of feature amounts of the frequency domain and then compressed on the basis of a human auditory model algorithm or the like.

In such a case, it is necessary to perform a process in units of frames in order to decompress the compressed audio, and it is indispensable to allocate a memory resource in units of frames. However, in the audio compression where sampling is not performed on a sampling frequency, such as the FLAC, there is no need to perform a process in units of frames, and divided decoding in units of frames or smaller can be inherently performed.

Further, even in the audio compression in which sampling is performed on a sampling frequency, in a case where the unit of audio data to be sampled is smaller than the frame size, divided decoding in units of frames or smaller (in units of frequency conversion) is available.

However, audio compression formats usually assume decoding in units of frames. For that reason, even if the divided decoding is attempted, the top position of the right-channel data (Right Date in FIG. 2) is not known, and thus execution of the divided decoding fails. In the present technology, specifying the top position of the right-channel data allows execution of the divided decoding, as will be described below.

### First Embodiment

An information processing apparatus according to a first embodiment of the present technology will be described.

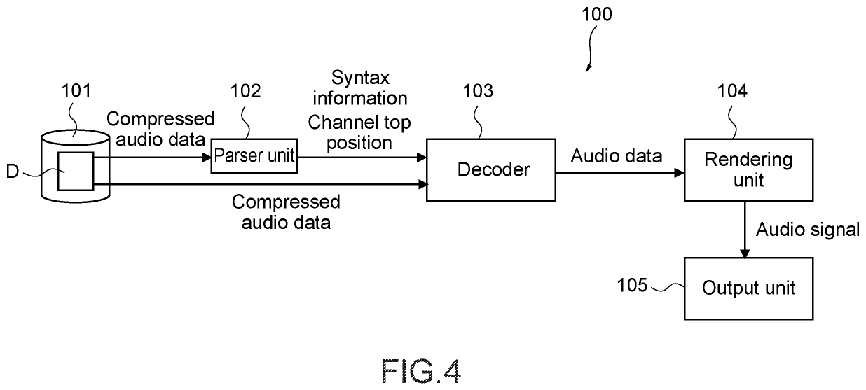

FIG. 4 is a block diagram showing a functional configuration of an information processing apparatus 100 according to this embodiment. As shown in FIG. 4, the information processing apparatus 100 includes storage 101, a parser unit 102, a decoder 103, a rendering unit 104, and an output unit 105.

Note that the storage 101 and the output unit 105 may be provided separately from the information processing apparatus 100 and connected to the information processing apparatus 100.

The storage 101 is a storage device such as an embedded multi-media card (eMMC) or an SD card and stores compressed audio data D to be decoded by the information processing apparatus 100. The compressed audio data D is audio data compressed by a compression codec such as the FLAC.

Note that the codec capable of being decoded by the method of the present technology is not limited to the FLAC, and includes a compression codec that does not sample a sampling frequency or a compression codec that samples a sampling frequency, in which sampling is performed in units of audio data smaller than the frame size. Specifically, Vorbis can be decoded by the method of the present technology.

The parser unit 102 acquires the compressed audio data D from the storage 101 and analyzes the syntax described in a stream header and a frame header. The parser unit 102 supplies syntax information, which is a parsing result, to the decoder 103.

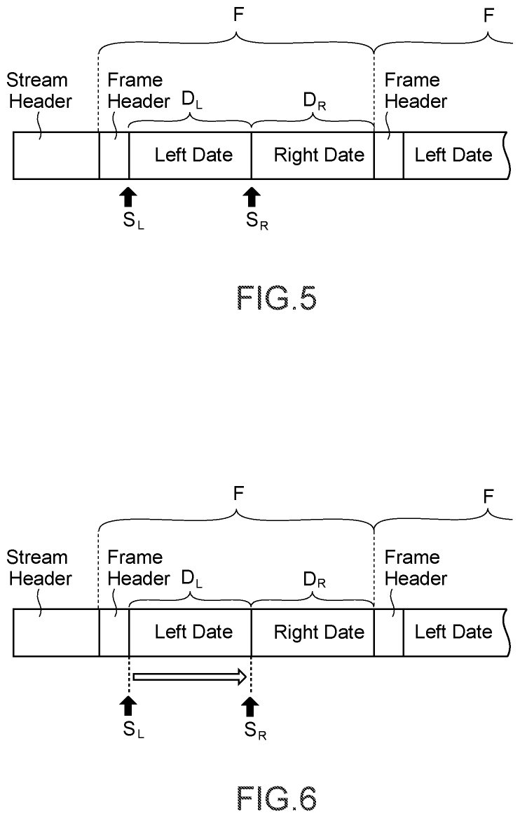

In addition, the parser unit 102 specifies the top position (hereinafter, referred to as channel top position) of each channel included in each frame of the compressed audio data D. FIG. 5 is a schematic diagram showing the channel top position in the compressed audio data D. As shown in the figure, the parser unit 102 specifies a top position S_{L} of the left-channel data (Left Date: hereinafter, D_{L}) and a top position S_{R} of the right-channel data (Right Date: hereinafter, D_{R}).

Here, since the top position S_{L} is immediately after the frame header, the parser unit 102 is capable of setting the end position of the frame header as the top position S_{L}. Meanwhile, the top position S_{R} is disposed behind the left-channel data D_{L}, and thus the parser unit 102 fails to specify the top position S_{R} as it is.

Here, the parser unit 102 is capable of specifying the top position S_{R} by decoding. FIG. 6 is a schematic diagram showing a mode of decoding by the parser unit 102. As shown by the white arrow in the figure, the parser unit 102 executes decoding from the top of the left-channel data D_{L}.

When the parser unit 102 completes decoding of the left-channel data D_{L}, the top position S_{R} of the right-channel data D_{R} is determined, and thus the parser unit 102 is capable of specifying the top position S_{R}.

Thus, the parser unit 102 only needs to decode the left-channel data D_{L}. Note that the data generated by this decoding is deleted because it is not used. Therefore, this process needs no memory resources.

The parser unit 102 supplies the channel top position, together with the syntax information, to the decoder 103.

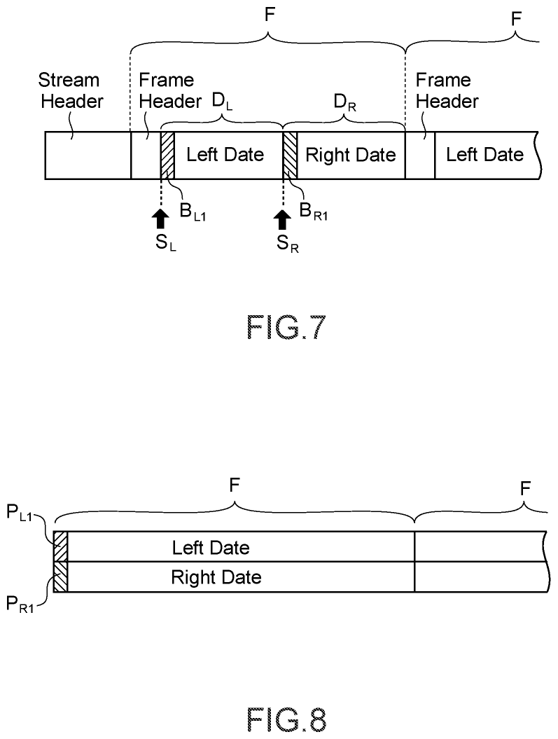

The decoder 103 decodes the compressed audio data using the channel top position and the syntax information. FIG. 7 is a schematic diagram showing a mode of decoding by the decoder 103. As shown in the figure, the decoder 103 reads from the storage 101 a block B_{L1} that is a block with a predetermined size from the top position S_{L} of the left-channel data D_{L}, and then decodes the block.

The size of the block B_{L1} is not particularly limited, and a size that allows the information processing apparatus 100 to optimize the use of an available memory resource is suitable. Typically, the size of the block B_{L1} is approximately 3 to 10% of the size of the left-channel data D_{L}.

Subsequently, the decoder 103 reads from the storage 101 a block B_{R1} that is a block with a predetermined size from the top position S_{R} of the right-channel data D_{R}, and then decodes the block. The size of the block B_{R1} is nearly equal to that of the block B_{L1}, and can be approximately 3 to 10% of the size of the right-channel data D_{R}.

FIG. 8 is a schematic diagram showing a data structure of the audio data (PCM data) generated by the decoder 103. As shown in the figure, audio data P_{L1}, which is a decoding result of the block B_{L1}, and audio data PR_{R1}, which is a decoding result of the block B_{R1}, are generated.

The rendering unit 104 interleaves the audio data P_{L1} 0 and the audio data P_{R1} for rendering, and supplies the generated audio signal to the output unit 105. The output unit 105 supplies the audio signal to an output device such as a speaker for output.

Since the audio data P_{L1} and the audio data P_{R1} are generated from the block B_{L1} and the block BRA, respectively, the audio data P_{L1} and the audio data P_{R1} have a smaller size than the size of the audio data corresponding to one frame generated from the left-channel data D_{L} and the right-channel data D_{R} (see FIGS. 3 and 8).

Hereinafter, the decoder 103 decodes the left-channel data D_{L} and the right-channel data D_{R} for each block, and the rendering unit 104 renders the generated audio data.

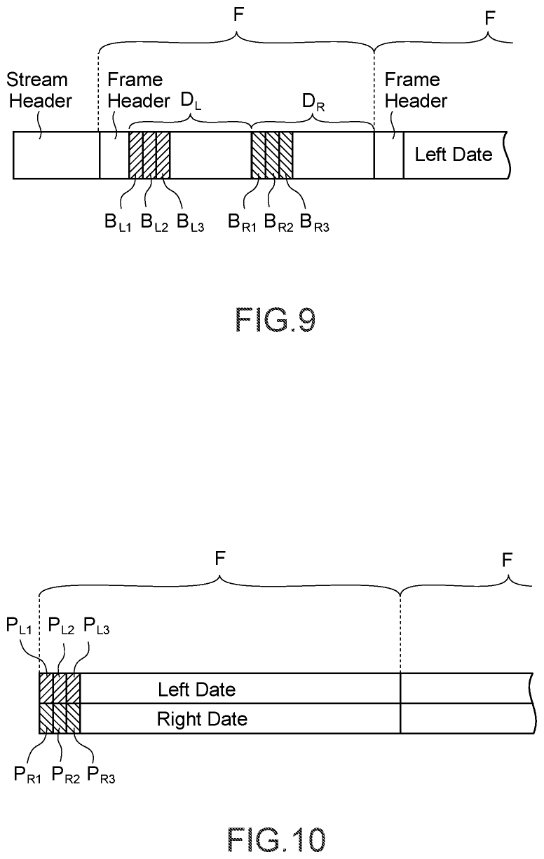

FIG. 9 is a schematic diagram showing the order of decoding by the decoder 103 of the decoder 103, and FIG. 10 is a schematic diagram showing the data structure of the audio data (PCM data) generated by the decoder 103.

As shown in FIG. 9, after decoding the block B_{R1}, the decoder 103 reads and decodes a block B_{L2} with a predetermined size from the end position of the block B_{L1} and generates audio data P_{L2}. Subsequently, the decoder 103 reads and decodes a block B_{R}2 with a predetermined size from the end position of the block B_{R1} and generates audio data P_{R2}.

When the audio data P_{L2} and the audio data P_{R2} are generated, the rendering unit 104 interleaves the audio data P_{L}2 and the audio data P_{R2} for rendering, and supplies the generated audio signal to the output unit 105.

Hereinafter, the decoder 103 decodes the left-channel data D_{L} and the right-channel data D_{R} in a block B_{L3} and a block B_{R3} and the following blocks to the respective end positions for each block in a similar manner, and generates audio data. The rendering unit 104 sequentially renders the audio data.

For the next frame and the following frames as well, the information processing apparatus 100 executes decoding in a similar process. That is, the parser unit 102 specifies the top position S_{L} and the top position S_{R} for each frame of the compressed audio data D, and the decoder 103 performs decoding for each block. The rendering unit 104 renders and outputs the audio data generated for each block.

As described above, since the parser unit 102 specifies the channel top position, the decoder 103 is capable of decoding the compressed audio data D for each block. As a result, the rendering unit 104 is capable of outputting audio data having a small size.

Thus, the data size stored in each of the ES buffers 1 and 2 and the PCM buffers 1 and 2 (see FIG. 1) corresponds to approximately two blocks (two left and right channels), which is significantly smaller than that in the case of decoding for each frame (see FIGS. 2 and 3). This can reduce the amount of the memory resource necessary for decoding.

Further, since the parser unit is also used in a normal decoding process, the decoding process according to the present technology can be achieved without necessity of a special processing engine.

### Modified Example

In the above description, it is assumed that the compressed audio data D is stored in the storage 101, but the compressed audio data D may be stored in another information processing apparatus or on a network, and the parser unit 102 and the decoder 103 may acquire compressed audio data by communication.

Further, in the above description, it is assumed that the left-channel data D_{L} is arranged next to the frame header, and the right-channel data D_{R} is arranged next to the left-channel data D_{L}, but the order of the left-channel data D_{L} and the right-channel data D_{R} may be reversed. In this case, the parser unit 102 is capable of specifying the top position S₁ of the left-channel data D_{L} by decoding.

Further, the compressed audio data is not limited to include the two left and right channels, but may include more channels such as 5.1 channels or 8 channels. Even in this case, the parser unit 102 specifies the channel top position for each channel, which allows the decoder 103 to execute decoding for each block.

In addition, it is assumed that the parser unit 102 specifies the channel top position by decoding, but in a case where the compressed audio data D includes in advance information indicating the channel top position, the channel top position can also be specified by using such information without decoding.

[Regarding Hardware Configuration]

The functional configuration of the information processing apparatus 100 described above can be achieved by cooperation of hardware and programs.

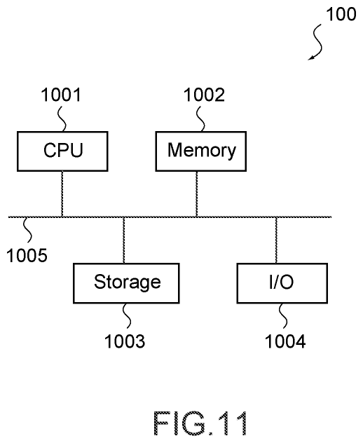

FIG. 11 is a schematic diagram showing a hardware configuration of the information processing apparatus 100. As shown in the figure, the information processing apparatus 100 includes, as a hardware configuration, a central processing unit (CPU) 1001, a memory 1002, storage 1003, and an input/output unit (I/O) 1004. Those are connected to one another by a bus 1005.

The CPU 1001 controls other configurations according to a program stored in the memory 1002, and also performs data processing according to the program and stores processing results in the memory 1002. The CPU 1001 can be a microprocessor.

The memory 1002 stores programs to be executed by the CPU 1001 and data. The memory 1002 can be a random access memory (RAM).

The storage 1003 stores programs and data. The storage 1003 may be a hard disk drive (HDD) or a solid state drive (SSD).

The input/output unit 1004 receives an input to the information processing apparatus 100, and supplies an output of the information processing apparatus 100 to the outside. The input/output unit 1004 includes an input device such as a touch panel or a keyboard, an output device such as a display, and a connection interface such as a network.

The hardware configuration of the information processing apparatus 100 is not limited to the hardware configuration shown herein and may be any hardware configuration capable of achieving the functional configuration of the information processing apparatus 100. Further, part or all of the above hardware configuration may exist on a network.

### Second Embodiment

An information processing apparatus according to a second embodiment of the present technology will be described.

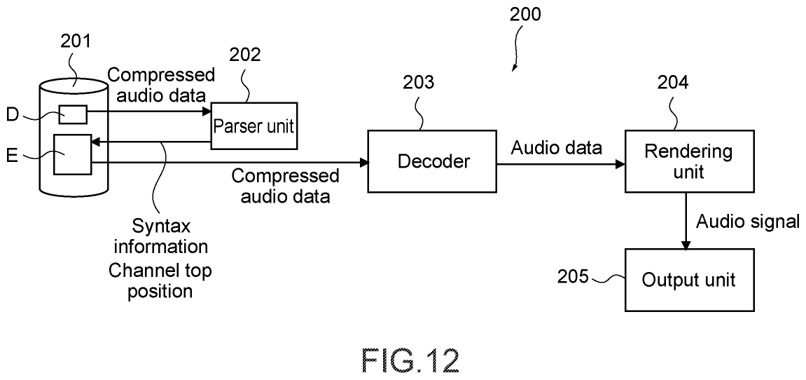

FIG. 12 is a block diagram showing a functional configuration of an information processing apparatus 200 according to this embodiment. As shown in FIG. 12, the information processing apparatus 200 includes storage 201, a parser unit 202, a decoder 203, a rendering unit 204, and an output unit 205.

Note that the storage 201 and the output unit 205 may be provided separately from the information processing apparatus 200 and connected to the information processing apparatus 200. Further, the parser unit 202 may also be provided in an information processing apparatus different from the information processing apparatus 200 and connected to the storage 201.

The storage 201 is a storage device such as an eMMC or an SD card and stores compressed audio data D to be decoded by the information processing apparatus 200. The compressed audio data D is audio data compressed by a compression codec such as the FLAC as described above.

Similarly to the first embodiment, the codec capable of being decoded by the information processing apparatus 200 is not limited to the FLAC, and includes a compression codec that does not sample a sampling frequency or a compression codec that samples a sampling frequency, in which sampling is performed in units of audio data smaller than the frame size.

In addition, the storage 201 stores compressed audio data E with meta-information. The compressed audio data E with meta-information is compressed audio data D to which meta-information is added, which will be described later in detail.

The parser unit 202 acquires the compressed audio data D from the storage 201 and analyzes the syntax described in a stream header and a frame header to generate syntax information.

In addition, the parser unit 202 specifies the top position (channel top position) of each channel included in each frame of the compressed audio data D. The channel top position includes the top position S_{L} of the left-channel data D_{L} and the top position S_{R} of the right-channel data D_{R} (see FIG. 5).

Since the top position S_{L} is immediately after the frame header, the parser unit 202 is capable of setting the end position of the frame header as the top position S_{L}. Further, the parser unit 202 is capable of executing decoding from the top of the left-channel data D_{L} in a similar manner to the first embodiment (see FIG. 6) and acquiring the top position S_{R}.

The parser unit 202 adds meta-information, which includes the channel top position and the syntax information, to the compressed audio data D to generate the compressed audio data E with meta-information, and stores the compressed audio data E with meta-information in the storage 201. Although a specific example of the meta-information will be described later, the meta-information only needs to include at least the top position of each channel for each frame.

The generation of the compressed audio data E with meta-information by the parser unit 202 can be executed at an optional timing before the decoder 203 executes decoding.

The decoder 203 decodes the compressed audio data using the channel top position and the syntax information. The decoder 203 is capable of reading the compressed audio data E with meta-information from the storage 201 and acquiring the channel top position included in the compressed audio data E with meta-information.

The decoder 203 decodes the compressed audio data D using the channel top position in a similar manner to the first embodiment. That is, the decoder 203 reads the block BLI that is part of the left-channel data D_{L} from the top position S_{L}, and then decodes the block B_{L1}, and reads the block B_{R1} that is part of the right-channel data D_{R} from the top position S_{R}, and then decodes the block B_{R1} (see FIG. 7).

Thus, the audio data P_{T}A that is a decoding result of the block B_{L1}, and the audio data P_{R1} of a decoding result of the block B_{R1} are generated (see FIG. 8).

The rendering unit 204 interleaves the audio data P_{L1} and the audio data P_{R1} for rendering, and supplies the generated audio signal to the output unit 205. The output unit 205 supplies the audio signal to an output device such as a speaker for output.

Hereinafter, in a similar manner to the first embodiment, the decoder 203 reads and decodes the left-channel data D_{L} and the right-channel data D_{R} for each block, and the rendering unit 204 renders the generated audio data (see FIG. 9).

For the next frame and the following frames as well, the information processing apparatus 200 executes decoding in a similar manner. That is, the decoder 203 acquires the channel top position of each frame from the compressed audio data E with meta-information, and decodes the compressed audio data D for each block. The rendering unit 204 renders and outputs the audio data generated for each block.

As described above, since the parser unit 202 specifies the channel top position, the decoder 203 is capable of decoding the compressed audio data D for each block. As a result, the rendering unit 204 is capable of outputting audio data having a small size.

Thus, the data size stored in each of the ES buffers 1 and 2 and the PCM buffers 1 and 2 (see FIG. 1) corresponds to approximately two blocks (two left and right channels), which is significantly smaller than that in the case of decoding for each frame (see FIGS. 2 and 3). This can reduce the amount of the memory resource necessary for decoding.

Further, in this embodiment, use of the compressed audio data E with meta-information allows decoding to be executed without a synchronous operation between the parser unit 202 and the decoder 203. This allows the parser unit 202 and the decoder 203 to be less susceptible to the influence such as fluctuations in the process amount or the like.

Further, since the parser unit 202 is capable of performing a parsing process (syntax analysis and specifying of the channel top position) in advance before receiving an actual decoding request, it is not necessary to perform a parsing process in actual decoding and it is also possible to reduce the access load to the processor power and the storage in an audio reproduction process.

Further, the meta-information is defined in a predetermined format and is created not in an edge terminal such as a wearable terminal or an IoT device but in, for example, a PC, a server, a cloud, or the like, and thus it is possible to achieve decoding according to this embodiment without performing a parsing process in the edge terminal.

In addition, the meta-information is held in the compressed audio data, and thus decoding by the method of this embodiment or normal decoding can be selected by an audio reproduction terminal. This allows the compressed audio data to be reproduced regardless of a reproduction environment.

### Modified Example

When executing the parsing process, the parser unit 202 may generate a meta-information file including no compressed audio data, instead of generating the compressed audio data E with meta-information.

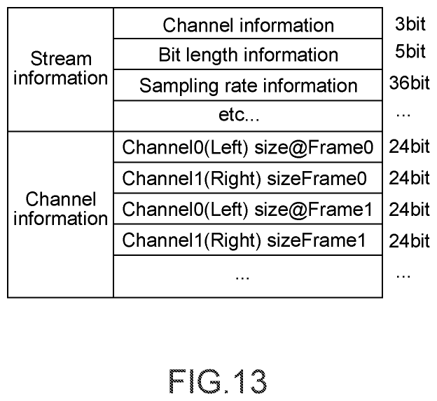

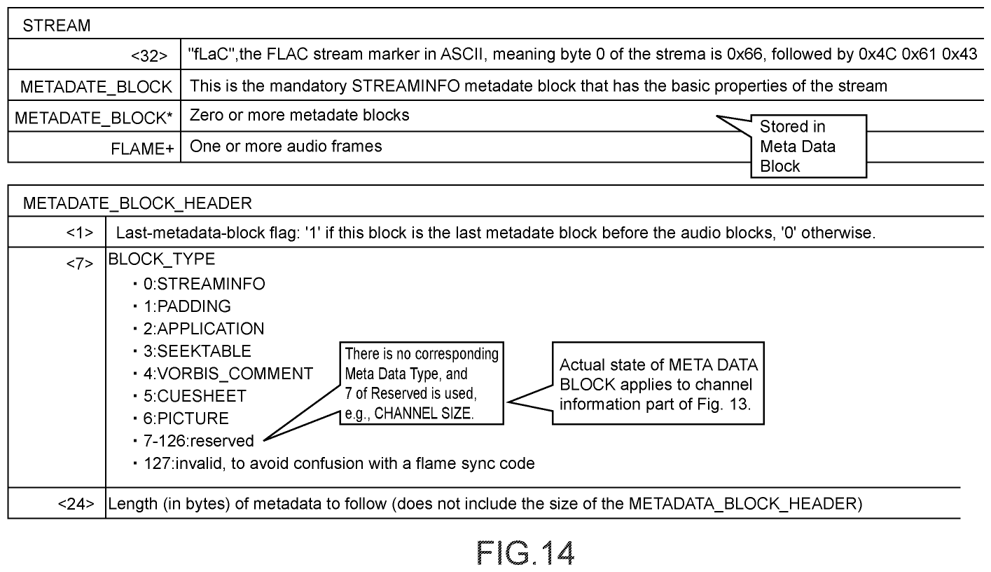

FIG. 13 is an example of a meta-information file. As shown in the figure, the meta-information file may be a file that stores stream information and size information for each channel data of each frame. The decoder 203 is capable of executing decoding from the channel top position for each block with reference to the meta-information.

Further, the parser unit 202 is also capable of storing the meta-information in a database (playlist data or the like) held by a music generating device or the like.

Note that in the above description it is assumed that the compressed audio data D and the compressed audio data E with meta-information are stored in the storage 201, but those pieces of data may be stored in another information processing apparatus or on a network, and the parser unit 202 and the decoder 203 may acquire those pieces of data by communication.

Further, in the above description, it is assumed that the left-channel data D_{L} is arranged next to the frame header, and the right-channel data D_{R} is arranged next to the left-channel data D_{L}, but the order of the left-channel data D_{L} and the right-channel data D_{R} may be reversed. In this case, the parser unit 202 is capable of acquiring the top position S_{L} of the left-channel data D_{L} by decoding.

In addition, the compressed audio data is not limited to include the two left and right channels, but may include more channels such as 5.1 channels or 8 channels. Even in this case, the parser unit 202 specifies the channel top position for each channel, which allows the decoder 203 to execute decoding for each block.

[Regarding Example of Embedding Meta-information in FLAC]

FIG. 14 is an example of the syntax of compressed audio data by the FLAC. As shown in the figure, the type of META DATA BLOCK HEADER is newly created in META DATA BLOCK (e.g., used as CHANNEL_SIZE in BLOCK TYPE 7), and the data format of the channel information shown in FIG. 13 is written to the actual state of META DATA BLOCK, thus achieving the compressed audio data E with meta-information.

[Regarding Hardware Configuration]

The functional configuration of the information processing apparatus 200 described above can be achieved by cooperation of hardware and programs. The hardware configuration of the information processing apparatus 200 can be similar to the hardware configuration according to the first embodiment (see FIG. 11).

Further, as described above, the parser unit 202 may be achieved by an information processing apparatus different from the information processing apparatus including the decoder 203 and the rendering unit 204, that is, this embodiment may be implemented by an information processing system including a plurality of information processing apparatuses.

Note that the present technology can take the following configurations.

(1) An information processing apparatus, including

a decoder that acquires a top position of each piece of data of a plurality of channels included in each frame of compressed audio data and decodes the data of the plurality of channels for each block with a predetermined size from the top position.

(2) The information processing apparatus according to (1), in which

each frame of the compressed audio data includes data of a first channel and data of a second channel sequentially from a top of the frame, and

the decoder decodes a first block from the top position in the first channel, decodes a second block from the top position in the second channel, decodes a third block from an end position of the first block in the first channel, and decodes a fourth block from an end position of the second block in the second channel.

(3) The information processing apparatus according to (1) or (2), further including

a parser unit that specifies the top position.

(4) The information processing apparatus according to (3), in which

the parser unit decodes the compressed audio data and specifies the top position.

(5) The information processing apparatus according to (4), in which

each frame of the compressed audio data includes data of a first channel and data of a second channel sequentially from a top of the frame, and

the parser unit decodes the data of the first channel and specifies an end position of the data of the first channel as a top position of the data of the second channel.

(6) The information processing apparatus according to (3), in which

the parser unit specifies the top position from meta-information of the compressed audio data.

(7) The information processing apparatus according to (4) or (5), in which

the parser unit specifies the top position and generates meta-information of the compressed audio data including the top position, and

the decoder decodes the data of the plurality of channels for each block with the predetermined size from the top position by using the top position included in the meta-information.

(8) The information processing apparatus according to (7), in which

the parser unit generates compressed audio data including the meta-information.

(9) The information processing apparatus according to (7), in which

the parser unit generates a meta-information file including the meta-information.

(10) The information processing apparatus according to any one of (2) to (9), further including

a rendering unit that renders audio data of the first block and audio data of the second block after the decoder decodes the first block and the second block.

(11) An information processing system, including:

a first information processing apparatus including
a decoder that acquires a top position of each piece of data of a plurality of channels included in each frame of compressed audio data and decodes the data of the plurality of channels for each block with a predetermined size from the top position; and

a second information processing apparatus including
a parser unit that specifies the top position.

(12) A program, which causes an information processing apparatus to operate as a decoder that acquires a top position of each piece of data of a plurality of channels included in each frame of compressed audio data and decodes the data of the plurality of channels for each block with a predetermined size from the top position.

(13) An information processing method, including

by a decoder, acquiring a top position of each piece of data of a plurality of channels included in each frame of compressed audio data and decoding the data of the plurality of channels for each block with a predetermined size from the top position.

### REFERENCE SIGNS LIST

100 information processing apparatus
101 storage
102 parser unit
103 decoder
104 rendering unit
105 output unit
200 information processing apparatus
201 storage
202 parser unit
203 decoder
204 rendering unit
205 output unit

1. An information processing apparatus, comprising
a decoder that acquires a top position of each piece of data of a plurality of channels included in each frame of compressed audio data and decodes the data of the plurality of channels for each block with a predetermined size from the top position.

2. The information processing apparatus according to claim 1, wherein
each frame of the compressed audio data includes data of a first channel and data of a second channel sequentially from a top of the frame, and
the decoder decodes a first block from the top position in the first channel, decodes a second block from the top position in the second channel, decodes a third block from an end position of the first block in the first channel, and decodes a fourth block from an end position of the second block in the second channel.

3. The information processing apparatus according to claim 1, further comprising
a parser unit that specifies the top position.

4. The information processing apparatus according to claim 3, wherein
the parser unit decodes the compressed audio data and specifies the top position.

5. The information processing apparatus according to claim 4, wherein
each frame of the compressed audio data includes data of a first channel and data of a second channel sequentially from a top of the frame, and
the parser unit decodes the data of the first channel and specifies an end position of the data of the first channel as a top position of the data of the second channel.

6. The information processing apparatus according to claim 3, wherein
the parser unit specifies the top position from meta-information of the compressed audio data.

7. The information processing apparatus according to claim 4, wherein
the parser unit specifies the top position and generates meta-information of the compressed audio data including the top position, and
the decoder decodes the data of the plurality of channels for each block with the predetermined size from the top position by using the top position included in the meta-information.

8. The information processing apparatus according to claim 7, wherein
the parser unit generates compressed audio data including the meta-information.

9. The information processing apparatus according to claim 7, wherein
the parser unit generates a meta-information file including the meta-information.

10. The information processing apparatus according to claim 2, further comprising
a rendering unit that renders audio data of the first block and audio data of the second block after the decoder decodes the first block and the second block.

11. An information processing system, comprising:
a first information processing apparatus including
a decoder that acquires a top position of each piece of data of a plurality of channels included in each frame of compressed audio data and decodes the data of the plurality of channels for each block with a predetermined size from the top position; and
a second information processing apparatus including a parser unit that specifies the top position.

12. A program, which causes an information processing apparatus to operate as a decoder that acquires a top position of each piece of data of a plurality of channels included in each frame of compressed audio data and decodes the data of the plurality of channels for each block with a predetermined size from the top position.

13. An information processing method, comprising
by a decoder, acquiring a top position of each piece of data of a plurality of channels included in each frame of compressed audio data and decoding the data of the plurality of channels for each block with a predetermined size from the top position.
